(19) United States
(12) Patent Application Publication
(10) Pub. No.: US 2008/0280383 A1
(43) Pub. Date: Nov. 13, 2008

(54) Method of real-time monitoring implantation

(76) Inventors: Ta-Yung Wang, Hsinchu City (TW); Chia-Hung Sun, Fongshan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/822,755

(22) Filed: Jul. 10, 2007

(30) Foreign Application Priority Data
May 9, 2007 (TW) 96116528

(51) Int. Cl. H01L 21/66

(52) U.S. Cl. 438/17; 257/E21.531

(57) ABSTRACT

A method of real-time monitoring implantation includes plotting a calibration curve for monitoring implantation first. Next, a testing substrate covered a photoresist is provided and then implanted. Since photoresist surface roughness will be changed after implantation, surface roughness change could be quantitatively determined by monitoring scattering light. Finally, the detected scattering light intensity is used to calculate the corresponding implantation condition by the use of the calibration curve.

### RELATED APPLICATIONS

This application claims priority to Taiwan Application Serial Number 96116528, filed May 9, 2007, which is herein incorporated by reference.

### BACKGROUND

1. Field of Invention

The present invention relates to a method for monitoring a manufacturing process of a semiconductor device. More particularly, the present invention relates to a method of real-time monitoring implantation.

2. Description of Related Art

In the semiconductor manufacturing process, implantation is used for modifying electrical properties of silicon wafer by bombarding silicon wafer with some specific ions. Moreover, by changing the conditions of the implantation, such as ion concentration, implantation energy, or implantation angle etc., it can manufacture different kinds of semiconductor devices to satisfy different needs. Therefore, how to control the conditions of implantation in real-time is very important.

In conventional techniques, electrical property analysis, secondary ion mass spectroscopy (SIMS) or four-point probes are used to monitor the conditions of implantation. SIMS is to bombard a surface of a testing sample with a beam of first high energy ions. After that, the energy of the first ion beam will be transferred to the testing sample and the substance in the surface of the testing sample is splattered which becomes ionic second ions. Next, the second ions are detected by instruments to obtain the information about the compositions and atomic distributions of the testing sample in vertical direction.

As regards the four-point probes, it is to insert two outer pins and two inner pins into the substrate and then apply electric currents between the outer pins to measure the voltage between the inner pins. Thus, sheet resistivity of the substrate is obtained. Since the sheet resistivity influenced by several factors, such as implantation concentration, film thickness, or crystal size, implantation information can be obtained by monitoring the sheet resistivity of the substrate.

No matter SIMS or the four-point probes, both of them are destructive methods which damage the surface of the wafer. Moreover, in a real manufacturing process, a standard wafer is implanted first and then detected by SMIS or the four-point probes. In order to reuse the standard wafer, the standard wafer has to be treated with chemical mechanical polishing or etching after finishing detection, and this is time and cost consuming.

In addition, electrical property analysis cannot be performed until the manufacturing process is completed. Therefore, the implantation condition cannot be monitored simultaneously during implantation, and this results in lots of defective products and increased manufacturing costs.

For the foregoing reasons, there is a need to develop a method for real time monitoring implantation and preventing the sample from being destructed. Meanwhile, it is also an important issue to cost down and save time.

### SUMMARY

The present invention provides a method of real-time monitoring implantation to prevent samples from being destructed and to efficiently control the process.

It is therefore an objective of the present invention to provide a method of real-time monitoring implantation. First, a plurality of standard substrates are provided, wherein the standard substrates are covered with a photoresist. Next, the standard substrates are implanted wherein a implantation condition for each of the standard substrates is changed. After that, photoresist surface roughnesses of the standard substrates are detected to obtain reference intensities of scattering lights. A calibration curve is plotted by using the reference intensities of scattering lights and the implantation conditions corresponding to the reference intensities. A testing substrate is provided wherein the testing substrate is covered with the photoresist. The testing substrate is implanted. A photoresist surface roughness of the testing substrate is detected to obtain a monitoring intensity of scattering light. Finally, the monitoring intensity of scattering light is scaled by using the calibration curve to analyze the implantation condition.

In the foregoing, this method of monitoring implantation not only prevents the sample from being destructed, but also costs down and saves time because the standard substrate can be reused by removing the photoresist on the substrate after finishing detection. In addition, the method above can be performed simultaneously during implantation, which is very efficient.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A is a profile of the substrate scanned by atomic force microscopy before implantation, according to one embodiment of this invention;

FIG. 1B is a profile of the substrate scanned by atomic force microscopy after implantation, according to one embodiment of this invention;

FIG. 2 is a flow chart of plotting a calibration curve of implantation energy for monitoring, according to one embodiment of this invention;

FIG. 3 is a calibration curve of implantation energy according to one embodiment of this invention;

FIG. 4 it is a calibration curve of implantation energy according to one embodiment of this invention;

FIG. 5 is a calibration curve of implantation concentration according to one embodiment of this invention;

FIG. 6 is a calibration curve of tilt angle according to one embodiment of this invention; and

FIG. 7 is a calibration curve of implantation energy according to one embodiment of this invention.

### DESCRIPTION OF THE PREFERRED EMBODIMENTS

Reference will now be made in detail to the present embodiments of the invention, examples of which are illustrated in the accompanying drawings. Wherever possible, the same reference numbers are used in the drawings and the description to refer to the same or like parts.

In the following embodiment, a method of real-time monitoring implantation is provided. By detecting the photoresist surface roughness before and after implantation, a calibration curve can be plotted and used as a standard for monitoring. To describe each embodiment in detail, it is necessary to introduce the affect of implantation on the photoresist first.

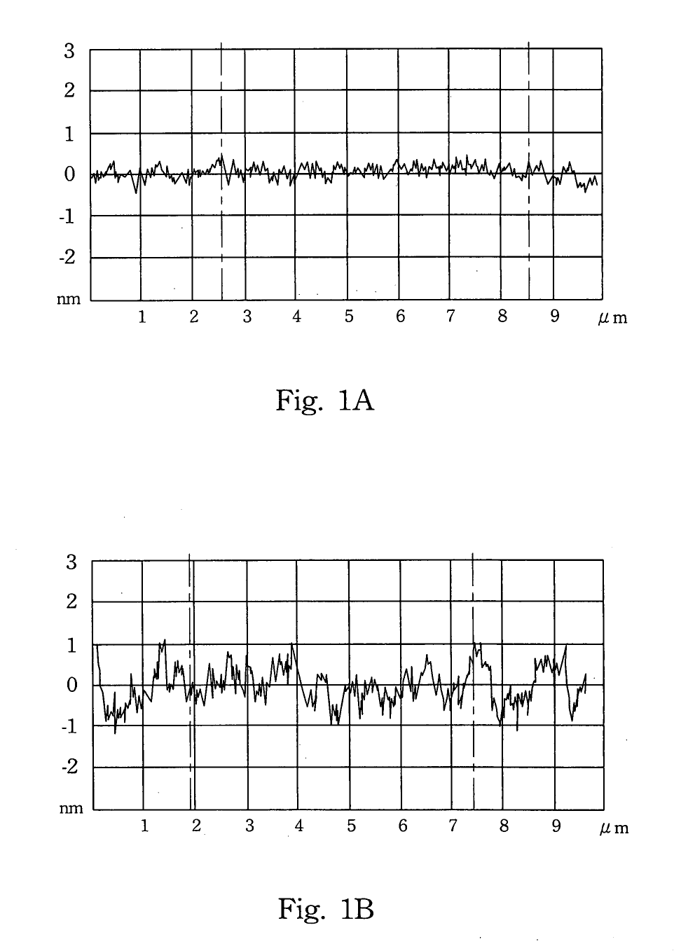

Young's modulus is a measure of material stiffness. The smaller Young's modulus indicates that the substance is easily deformed, which results in greater change of the roughness when the substance is treated with an external force. In general, Young's modulus of photoresists is usually smaller than 5 Gpa. Accordingly, if a substrate is covered with a photoresist, and then implanted, the implantation energy will change the photoresist surface roughness. To prove this assumption, a substrate was covered with a photoresist first, wherein the photoresist used can be I-line photoresist which comprises phenolic resin (Novolac), or deep ultraviolet light (DUV) photoresists, such as DUV photoresist (248 nm) that comprises acetal resin, or DUV photoresist (193 nm) that comprises acryl resin. After that, the photoresist on the substrate was scanned by atomic force microscopy (AFM) to detect the change of photoresist surface roughness. The results are shown as FIG. 1A and FIG. 1B.

FIG. 1A and FIG. 1B are profiles of the substrate scanned by atomic force microscopy (AFM) before and after implantation, respectively. Before implantation, the surface of the photoresist was smooth, so line fluctuation is smaller as shown in FIG. 1A. However, in FIG. 1B, after implantation, the 1o surface of the photoresist became less smooth because it was bombarded by ions. The photoresist surface roughness was greatly changed, so larger line fluctuation is expected and shown in FIG. 1B.

According to the AMF results obtained by AFM, it demonstrated that the photoresist surface roughness was greatly changed after implantation. Therefore a calibration curve can be plotted on the diagram of implantation conditions versus photoresist surface roughnesses of the photoresist. Moreover, the calibration curve can be used for monitoring implantation. In the following embodiments, the surface roughness was detected by Surfscan by detecting scattering light intensity from the photoresist surface. The stronger intensity of the scattering light indicates less smooth photoresist surface.

Oppositely, weaker scattering light intensity indicates smoother photoresist surface.

### (1) A Calibration Curve of Implantation Energy for Monitoring

According to the principle of energy conservation of, each ion had a particular kinetic energy provided by an implantation machine while doing implantation. However, after the ion left the machine and hit the photoresist, a part of the kinetic energy became work done to the photoresist, which is also called strain energy. Consequently, the surface roughness of the photoresist will be changed. The conversion between kinetic energy (K) and Strain energy (U) is as formula (1):

$$K = \frac{1}{2} {MV}^{2} = F * Δ X = U \qquad ( 1 )$$

Wherein V is the ion's velocity after leaving the implantation machine, and M is ion mass, and F is the force that ion applied to the photoresist, and ΔX is the displacement or the change of the surface roughness. According to formula (1), the change of the photoresist surface roughness is proportional to the implantation energy provided by the implantation machine, so a calibration curve can be plotted on the diagram of surface roughness versus implantation energy. The detailed process is described as follows.

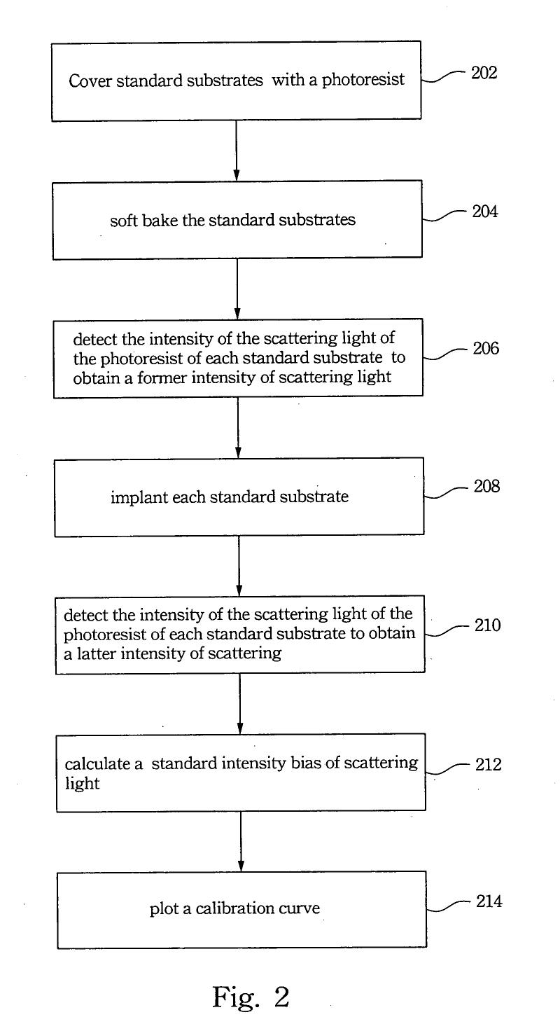

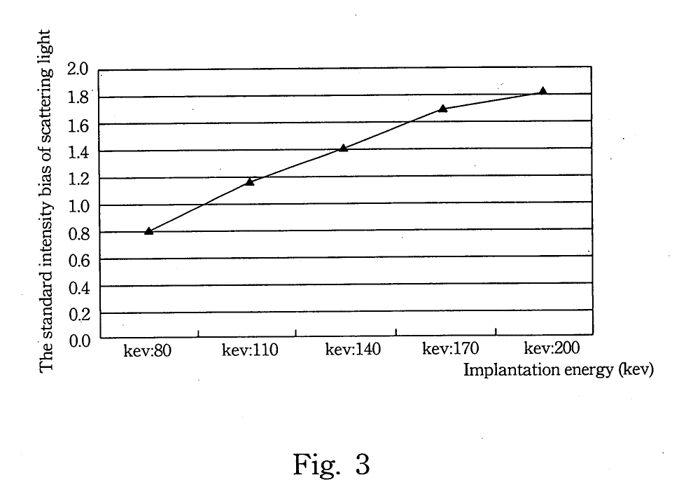

Referring to FIG. 2, it illustrates a flow chart of plotting a calibration curve of implantation energy for monitoring, according to one embodiment of this invention. First, several standard substrates were covered with a photoresist respectively (step 202), and then were soft baked to remove the solvent in the photoresist (step 204). Next, the scattering light intensity of the photoresist of each standard substrate was detected by Surfscan to obtain a former scattering light intensity for each standard substrate (step 206). The former intensity indicates the photoresist surface roughness before implantation. After that, each standard substrate was implanted by implantation machine without bias wherein the implantation concentration was identical but the implantation energy were different (step 208). In the embodiment of the present invention, the implantation concentration was 5×10¹³/cm², and 5 standard substrates were respectively implanted with different energies, 80 Kev, 110 Kev, 140 Kev, 170 Kev, and 200 Kev. After implantation, the scattering light intensity of the photoresist of each standard substrate was detected by Surfscan again to obtain a latter scattering light intensity for each standard substrate (step 210). Similarly, the latter intensity indicates the photoresist surface roughness after implantation. A standard intensity bias of scattering light was obtained by calculating the bias between the former scattering light intensity and the latter scattering light intensity (step 212). At this step, the standard intensity bias of scattering light obtained indicates the change of the surface roughness, ΔX. By using the standard intensity bias of scattering light of each standard substrate and the implantation energy corresponding to it, a calibration curve was plotted (step 214) and used as a monitoring standard shown in FIG. 3.

According to FIG. 3, it is a calibration curve of implantation energy according to one embodiment of this invention wherein X axis is implantation energy, and Y axis is the standard intensity bias of scattering light obtained from the standard substrates. According to FIG. 3, it is obvious that the implantation energy is proportional to the standard intensity bias of the scattering light. This shows that when the implantation machine provides more energy, it changes photoresist surface roughness more, so the intensity bias of scattering light increases. Accordingly, the result above proved the theory of formula (1). In addition, since the data in the figure were obtained after the implantation machine had been calibrated by utilizing the calibration curve, a testing substrate can be quantitatively analyzed to exam if the implantation energy provided conform to the standard or not, or if there is any bias in the implantation machine.

For example, the scattering light intensity of the photoresist of the testing substrate was detected before and after the implantation to obtain an intensity bias of scattering light. This intensity bias of scattering light is called the testing intensity bias of scattering light. After that, the testing intensity bias of scattering light was corresponded to the calibration curve of the implantation energy to figure out the implantation energy of the testing substrate. If the corresponding energy deviated from the calibration curve, it indicates that the implantation energy provided by the implantation machine is biased. The bias implantation energy will change the photoresist surface roughness of the testing substrate too much or too little. If the deviation is too large, beyond tolerance, it implies that the implantation machine is unstable. However, if the corresponding energy is located on the calibration curve, it implies that the implantation energy provided by the implantation machine is stable.

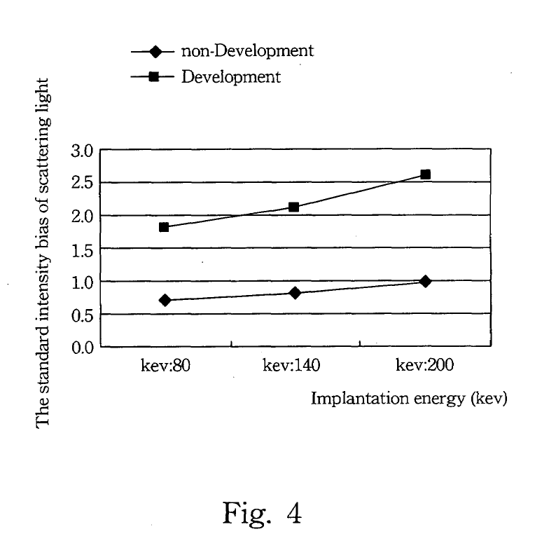

However, in the manufacturing process, photoresist must be processed by lithography before implantation. To understand the effect of lithography on detecting scattering light intensity mentioned above, therefore the steps of FIG. 2 were repeated again and the steps of exposure, post-exposure bake, and development were added after the step of soft bake. Finally, the implantation and scattering light detection were performed and the result is shown as FIG. 4.

According to FIG. 4, although photoresist was processed by lithography, the intensity bias of scattering light is still proportional to the implantation energy. Accordingly, the obtained calibration curve can be applied to monitor the implantation in manufacturing process. In addition, if the former scattering light intensity detected is maintained on a baseline, it indicates that the flatness of the photoresist is consistent before implantation. Thus, the step of detecting the former scattering light intensity can be skipped. The calibration curve can be plotted with the latter scattering light intensity detected after implantation, and the intensity bias of scattering light needs not to be calculated. Overall, no matter standard intensity bias or latter intensity, the intensity detected from the standard substrate and used for plotting a calibration curve are called reference intensity. Similarly, the intensity detected from the standard substrate and used for monitoring, no matter testing intensity bias or latter intensity, is called monitoring intensity.

### (2) A Calibration Curve of Implantation Concentration for Monitoring

In addition to the implantation energy, the implantation concentration is also one of important implantation conditions for monitoring. According to formula (2), when the energy provided by the implantation machine is steady, the higher implantation concentration indicates that the sum of the ion mass is larger and the total kinetic energy is larger, too. Therefore, the strain energy applied to the photoresist is increased which resulting in increasing the change of the roughness of the photoresist and the scattering light intensity. Hence, the implantation concentration is also proportional to the intensity bias of scattering light.

$$\sum K = \sum \frac{1}{2} {MV}^{2} = \sum F * Δ X = \sum U \qquad ( 2 )$$

Usually, in the manufacturing process, the implantation is increased exponentially. Accordingly, an exponential calibration curve of implantation concentration can be plotted on the diagram of intensity bias of scattering light versus logarithm of the implantation concentration.

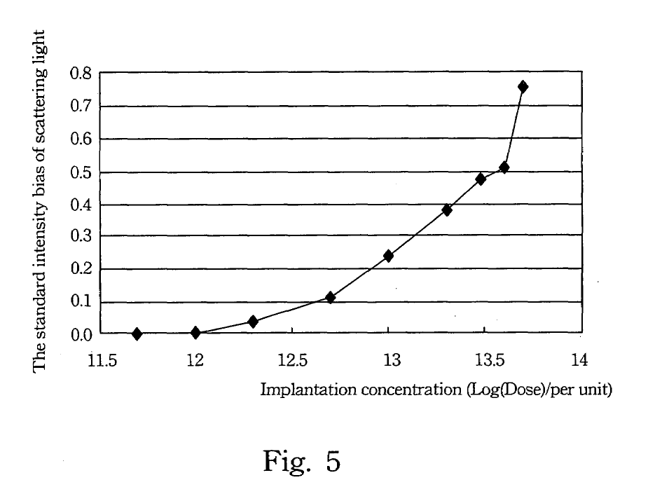

In the embodiment of the present invention, 9 standard substrates covered with a photoresist were implanted wherein the implantation energy was 80 Kev and the implantation concentration were 5×10¹¹/cm², 1×10¹²/cm², 2×1012/cm², 5×10¹²/cm², 1×10¹³/cm², 2×10¹³/cm², 3×10¹³/cm², 4×10¹³/cm², and 5×10¹³/cm². The calibration curve of implantation concentration plotted is shown as FIG. 5 and the detailed procedures for plotting were described above and not described herein.

Referring to FIG. 5, it is a calibration curve of implantation concentration according to one embodiment of this invention wherein X axis is logarithm of implantation concentration, Y axis is the standard intensity bias of scattering light obtained from the standard substrates. According to the calibration curve in FIG. 5, it indicates that the change of the photoresist surface roughness and the intensity bias of scattering light increase as the ion concentration increases. This proves the assumption of the implantation concentration and the change of the photoresist surface roughness mentioned above. Moreover, the data in the figure were obtained from the implantation machine without any implantation concentration deviation so the calibration curve can be used as a monitoring standard to quantitatively analyze the testing substrate.

### (3) A Calibration Curve of Implantation Title Angle for Monitoring

In the implantation process, another important implantation condition of for monitoring is tilt angle. Because of the characteristics of silicon lattice arrangement, there are long openings inside silicon wafer. If the moving direction of the ions implanted is parallel to these openings, ions are not able to bombard the silicon atoms completely which decrease the implantation efficiency. This is called tunnel effect. In order to reduce tunnel effect, ion implanting direction has to be tilted while implantation, the angle is called tilt angle. When ion beam incident direction is perpendicular to wafer surface, the tilt angle is 0°. therefore, when ion beam incident direction is parallel to wafer surface, the tilt angle is 90°.

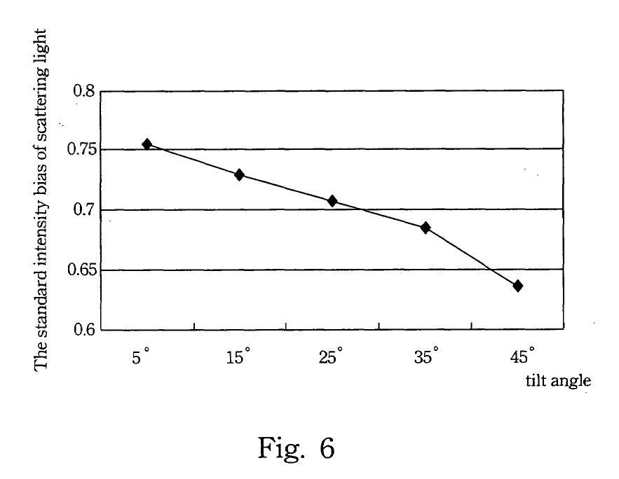

In the embodiment of the present invention, 9 standard substrates covered with a photoresist were implanted wherein the tilt angles were 5°, 15°, 25°, 35°, and 45° respectively. After that, a calibration curve of tilt angle was plotted on the basis of the procedures mentioned above. The relationship between the tilt angles and the scattering light intensities was obtained and used as a monitoring standard. The calibration curve of tilt angle is shown as FIG. 6.

Referring to FIG. 6, it illustrates a calibration curve of tilt angle according to one embodiment of this invention wherein X axis is tilt angle, and Y axis is the standard intensity bias of scattering light obtained from the standard substrates. According to the calibration curve in FIG. 6, it indicates that when the tilt angle is smaller, the impact on the photoresist caused by the ions is strong. Moreover, the change of the photoresist surface roughness is larger, so the intensity bias of scattering light becomes greater. In contrarily, when the tilt angle is larger, the impact on the photoresist caused by the ions is weaker. Therefore, the change of the photoresist surface roughness is decreased, and the intensity bias of scattering light is less. In view of the above, the intensity bias of scattering light detected is inverse proportional to the tilt angle, so the calibration curve plotted can be used as a monitoring standard.

### (4) Different Types of Photoresists

The method mentioned above is to plot a calibration curve by detecting the surface roughness of a photoresist. However, different types of photoresists will lead to different surface roughness change even if the implantation condition remains the same, because of different compositions or properties of these photoresists.

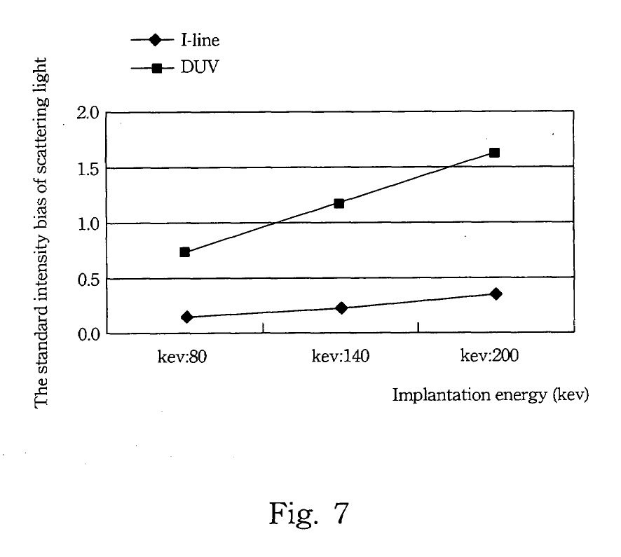

In the embodiment of the present invention, I-line photoresist (365 nm) and DUV photoresist (248 nm) were used to plot calibration curves of implantation energy on the basis of the procedures mentioned above. The calibration curves were therefore used to understand the effect photoresist composition on surface roughness change. In the embodiment of the present invention, the implantation concentration was 5×10¹³, and the implantation energies were 80 Kev, 140 Kev, and 200 Kev. The calibration curve is shown as FIG. 7.

Referring to FIG. 7, it is a calibration curve of implantation energy according to one embodiment of this invention wherein X axis is implantation energy, and Y axis is the standard intensity bias of scattering light obtained from the standard substrates. According to the figures, the implantation energy is proportional to the standard intensity bias of the scattering light for both I-line or DUV photoresist. However, DUV photoresist leads to stronger scattering light intensity bias under a same implantation energy. This indicates that surface roughness change of the DUV photoresist is higher than that of I-line photoresist. That is because DUV photoresist is much more fragile than I-line photoresist after exposure, so DUV photoresist leads to larger surface roughness change under a same implantation conditions. In view of the above, once if a new photoresist is used, a new calibration curve has to be plotted and used as a new monitoring standard.

In conclusion, by detecting scattering light intensity and using a calibration curve, the method provided above for monitoring implantation prevents the substrate from being destructed while monitoring. Moreover, this method can simultaneously determine if a implantation condition meets the standard requirement as well as understand if the performance of an implantation machine is deviated from calibrated standard.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of real-time monitoring implantation, comprising:
providing a plurality of standard substrates, wherein the standard substrates are covered with a photoresist;
implanting the standard substrates wherein a implantation condition is changed while implanting each of the standard substrates;
detecting photoresist surface roughnesses of the standard substrates to obtained reference intensities of scattering light of the standard substrates;
plotting a calibration curve by utilizing the reference intensities of scattering light and the implantation conditions corresponding to the reference intensities of scattering light;
providing a testing substrate, wherein the testing substrate is covered with the photoresist;
implanting the testing substrate;
detecting photoresist surface roughness of the testing substrate to obtain a monitoring intensity of scattering light;
scaling the monitoring intensity of scattering light by using the calibration curve of implantation to analyze the implantation condition.

2. The method of claim 1, wherein the implantation condition is implantation concentration, implantation energy, or tilt angle.
